(19) United States
(12) Patent Application Publication
(10) Pub. No.: US 2023/0411325 A1
(43) Pub. Date: Dec. 21, 2023

(54) CHIP PACKAGE INTEGRATION WITH HYBRID BONDING

(71) Applicant: XILINX, INC., San Jose, CA (US)

(72) Inventors: Inderjit SINGH, Saratoga, CA (US); Shih-Yen CHEN, Hsinchu City (TW); Yi-Ting CHEN, Taipei City (TW)

(21) Appl. No.: 17/841,454

(22) Filed: Jun. 15, 2022

(51) Int. Cl. H01L 23/00

(52) U.S. Cl. CPC H01L 24/08; H01L 24/80; H01L 24/03; H01L 24/05; H01L 2224/08225; H01L 2224/80447; H01L 2224/80895; H01L 2224/80896; H01L 2224/0361; H01L 2224/05647; H01L 2224/05147; H01L 2224/80379

(57) ABSTRACT

A chip package and method for fabricating the same are provided that includes hybrid bonds between a substrate and integrated circuit devices. In one example, a chip package includes a plurality of integrated circuit (IC) devices mounted on a substrate. The substrate has a die side and a ball side. The die side of the substrate includes a plurality of exposed metal bond pads. Each IC device has a device body. Functional circuitry is formed in the device body, terminating at a plurality of exposed metal bond pads. The plurality of exposed metal bond pads are hybrid bonded to the plurality of exposed metal bond pads.

### TECHNICAL FIELD

Embodiments of the present invention generally relate to a chip package having hybrid bonding, and in particular, to a chip package having both chiplets and integrated circuit dies boned to substrates, such as package substrates, interposers and the like.

### BACKGROUND

Electronic devices, such as tablets, computers, copiers, digital cameras, smart phones, control systems, automated teller machines, data centers, artificial intelligence system, and machine learning systems among others, often employ electronic components which leverage chip package assemblies for increased functionality and higher component density. Conventional chip packaging schemes often utilize a package substrate, often in conjunction with a through-silicon-via (TSV) interposer substrate, to enable a plurality of integrated circuit (IC) dies to be mounted to a single package substrate. The IC dies may include memory, logic or other IC devices.

In advanced chip-on-wafer (CoW) chip packages, the integration of large IC dies and chiplets is becoming increasingly challenging, particularly as fine pitch and high density interconnects at the IC die/chiplet to substrate interface are highly desirable to obtain performance goals. Some of these challenges at the interface include warpage control, prevention of solder joint defects such as bridging and poor reflow, and effective removal of flux residue. Failure to adequately address any of these challenges could lead to poor device performance and even device failure.

Therefore, a need exists for a chip package having an improved IC die/chiplet to substrate interface.

### SUMMARY

A chip package and method for fabricating the same are provided that includes hybrid bonds between a substrate and integrated circuit devices. In one example, a chip package includes a plurality of integrated circuit (IC) devices mounted on a substrate. The substrate has a die side and a ball side. The die side of the substrate includes a plurality of exposed metal bond pads. Each IC device has a device body. Functional circuitry is formed in the device body, terminating at a plurality of exposed metal bond pads. The plurality of exposed metal bond pads are hybrid bonded to the plurality of exposed metal bond pads.

In another example, the chip package may include a first bond pad of the plurality of exposed metal bond pads that has a surface area in contact with a first contact pad of the plurality of exposed metal bond pads. The surface area if the first bond pad is greater than a sectional area of the first bond pad taken in a direction parallel to a plane of the substrate.

In yet another example, a method for fabricating a chip package is provided. The method includes temporarily securing a plurality of integrated circuit (IC) devices to a carrier, revealing a plurality of metal bond pads of each IC device disposed on the carrier, mounting the IC devices disposed on the carrier to a substrate, hybrid bonding a plurality of exposed metal bond pads of the substrate to the metal bond pads of the IC devices disposed on the carrier, and removing the carrier to form the chip package. The hybrid bonds mechanically couple the IC devices to the substrate and electrically couple the functional circuitry of the IC devices to circuitry formed through the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow diagram of a method for forming a chip package.

FIG. 2 is a schematic representation of a plurality of integrated circuit (IC) devices mounted to a carrier being flipped onto a substrate in the process of forming a chip package.

FIG. 3 is a schematic representation of one of the plurality of IC devices disposed on the carrier and the substrate of FIG. 2 being bonded together.

FIG. 4 is a schematic sectional view of a chip package.

FIGS. 5-8 are schematic partial sectional exploded views of various bonding interfaces between the substrate and the IC device.

FIG. 9 is a flow diagram of a first portion of a method for preparing IC devices for inclusion in a chip package.

FIGS. 10A-10J are schematic sectional views of an IC device shown processing through various stages of preparation in accordance to the method described in FIG. 9.

FIG. 11 is a flow diagram of a method for preparing a substrate for inclusion in a chip package.

FIGS. 12A-12F are schematic sectional views of a substrate shown processing through various stages of preparation in accordance to the method described in FIG. 11.

To facilitate understanding, identical reference numerals have been used, where possible, to designate identical elements that are common to the figures. It is contemplated that elements of one embodiment may be beneficially incorporated in other embodiments.

### DETAILED DESCRIPTION

A chip package and method for fabricating the same are provided that enable fine pitch and high density interconnects at the IC die (and/or chiplet) to substrate interface. The interface leverages hybrid bonding techniques to enable formation of sub-micron fine pitches between interconnects, improves warpage resistance, eliminates flux residue In some examples, the hybrid bond across the interconnect interface is not completely parallel to the plane of the substrate, which desirably increases the surface area available for hybrid bonding, resulting in increased bond strength, improved electrical performance, and more relaxed tolerances. As an end result, the chip package with hybrid bonded interface provide improved reliability and performance over conventional solder interface designs.

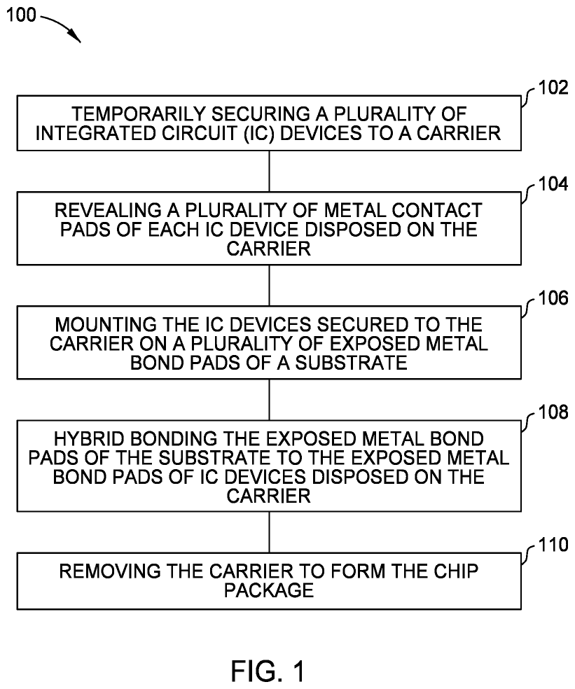

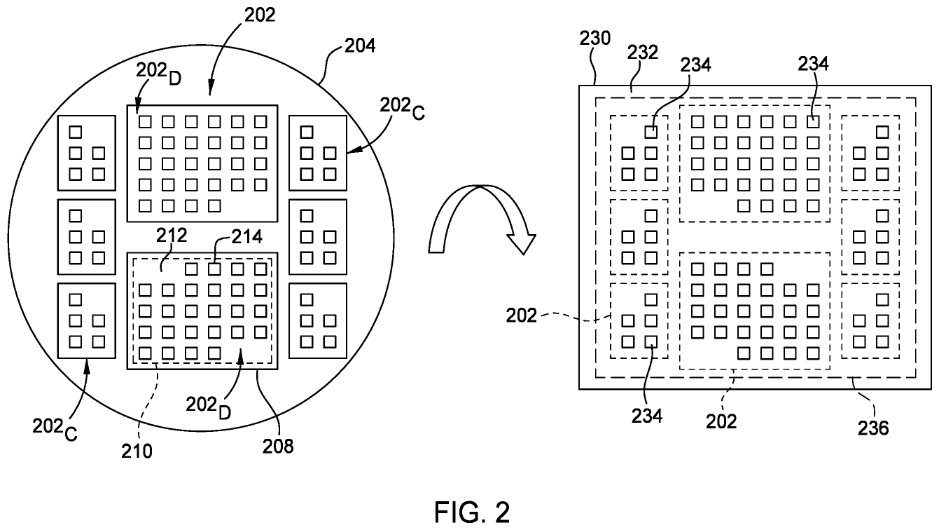

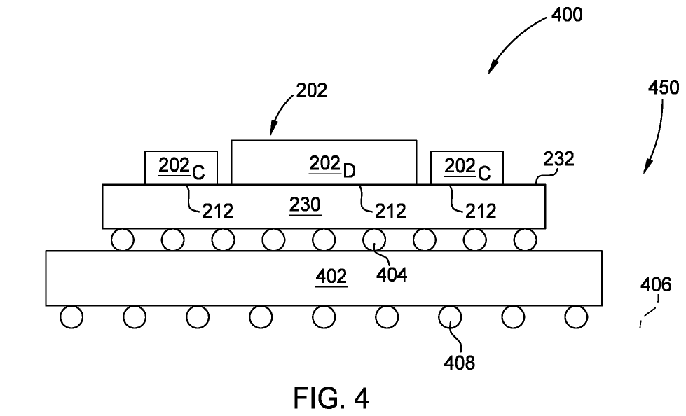

Turning now to FIG. 1, a flow diagram of a method 100 for forming a chip package is provided. The chip package may be configured as illustrated in FIG. 4, or have another suitable configuration. FIG. 2 is a schematic representation of a plurality of integrated circuit (IC) devices 202 mounted to a carrier 204 being flipped onto a substrate 206 in the process of forming the chip package in accordance to the method 100 of FIG. 1.

The method 100 begins at operation 102 by temporarily securing a plurality of integrated circuit (IC) devices 202 to a carrier 204, as shown in FIG. 2. The IC devices 202 may be one or more IC dies, one or more chiplets, or a combination of one or more IC dies and one or more chiplets. In example depicted in FIG. 2, the IC devices 202 mounted to the carrier 204 include two IC dies 202_{D} and six chiplets 202_{C}. The IC devices 202 may be mounted to the carrier 204 using a temporary adhesive, such as a die attach film or tape.

The carrier 204 may be any suitable rigid substrate that to which the IC devices 202 may be temporally secured during the hybrid bonding process. In one example, the carrier 204 is a metal plate, such as an aluminum plate. In another example, the carrier 204 is a glass or glass reinforced plastic plate.

The IC dies 202_{D} and chiplets 202_{C} each include a device body 208 having functional circuitry 210 formed in therein. The functional circuitry 210 may include block random access memory (BRAM), UltraRAM (URAM), digital signal processing (DSP) blocks, configurable logic elements (CLEs), and the like. The IC dies 202_{D} may be, but are not limited to, programmable logic devices, such as field programmable gate arrays (FPGA), memory devices, such as high band-width memory (HBM), optical devices, processors or other IC logic structures. The IC dies 202_{D} may optionally include optical devices such as photo-detectors, lasers, optical sources, and the like. In some examples, at least one of the IC dies 202_{D} is a logic die having math processor (also known as math engine) circuitry for accelerating machine-learning math operations in hardware, such as self-driving cars, artificial intelligence and data-center neural-network applications. In another example, at least one of the IC dies 202_{D} is a logic die, while the other IC die 202_{D} or one or more of the chiplets 202_{C} are memory devices.

Optionally, at least one or more of the IC devices 202 may be disposed in a vertical stack. It is contemplated that the IC devices 202 comprising a vertical stack may be the same or different types. An exemplary stack is a stack of memory dies. Although eight IC devices 202 are shown in FIG. 2, the number of IC devices 202 disposed on the carrier 204, and ultimately in the chip package, may vary from one to as many as can fit within the chip package.

The device body 208 of each IC device 202 has a die bottom surface 212 and a die top surface. The die top surface is attached to the carrier 204. The functional circuitry 210 is disposed within the device body 208 and includes routing that terminates on the die bottom surface 212 of the IC device 202, for example at bond pads 214.

After the IC device 202 is attached to the carrier 204, the method 100 continues to operation 104. At operation 104, the plurality of metal bond pads 214 of each IC device 202 disposed on the carrier 204 are revealed. The metal bond pads 214 may be revealed by any suitable technique, such as grinding, milling or etching.

At operation 106, the IC devices 202 disposed on the carrier 204 are mounted on a substrate 230. The substrate 230 may be an interposer or a package substrate. The substrate 230 includes circuitry 236 that connects bond pads 234 exposed on an IC device (i.e., top) surface 232 of the substrate 230 with bond pads exposed on the opposite (i.e., bottom) surface of the substrate. The bond pads 234 are arranged in groups that are in mirror image of the arrangement of the bond pads 214 of the IC devices 202 secured to the carrier 204. In this manner, when the carrier 204 is flipped and mounted on the substrate 230, each of the bond pads 214 of every IC devices 202 is aligned and in contact with the bond pads 234 of the IC devices 202 secured to the carrier 204. An outline of the mounting area of each IC device 202 on the substrate 230 is shown in phantom in FIG. 2.

Once the IC devices 202 have been mounted on the substrate 230, the exposed metal bond pads 234 of the substrate 230 are hybrid bonded to the exposed metal bond pads 214 of the IC devices 202 at operation 108. Hybrid bonding includes forming non-metal to non-metal bonds using fusion bonding, and forming metal-to-metal bonds. The metal-to-metal bonds may be formed using pressure and heat to form eutectic metal bonds. In one example, a hybrid bond is formed by bonding the dielectric materials surrounding the bond pads 214, 234 to first secure the substrate 230 and IC devices 202, followed by an interfusion of the metal materials of the bond pads 214, 234 to create the electric interconnect between the functional circuitry 210 of the IC devices 202 and the circuitry 236 of the substrate 230.

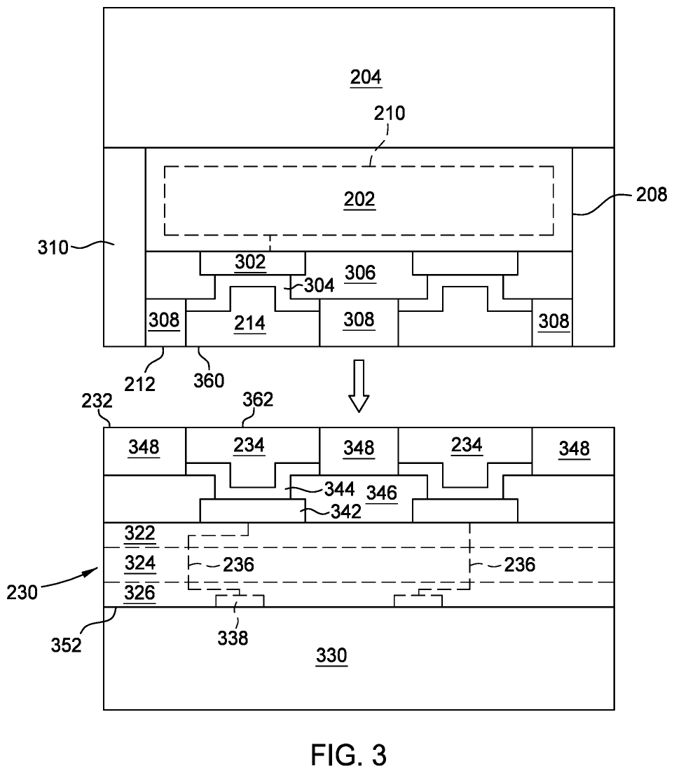

FIG. 3 is a schematic representation of one of the plurality of IC devices 202 disposed on the carrier 204 and the substrate 230 of FIG. 2 in the process of being urged together to form a hybrid bond. The other IC devices 202 not shown in FIG. 3 are similarly secured to the substrate 230. The substrate 230 may optionally be temporarily mounted to a carrier 330, which may be similar to the carrier 204 described above.

As illustrated in FIG. 3, the device body 208 includes a plurality of contact pads 302 that are electrically connected to the functional circuitry 210 of the IC devices. The plurality of contact pads 302 are separated by an internal dielectric layer 306. Each bond pad 214 is formed on and electrically connected to a respective one of the contact pads 302. In one example, the bond pad 214 is formed from plated copper that is disposed on a copper seed layer 304. Each bond pad 214 is separated from an external dielectric layer 308. The dielectric layer 308 is selected from a material suitable for hybrid bonding to another dielectric material. In one example, the dielectric layer 308 is polybenzoxazole (PBO), polyimide (PI), benzocyclobutene (BCB), a combination thereof or the like. The dielectric layer 308 and the bond pads 214 are exposed on the bottom surface 212 of the IC device to facilitate contact with the top surface 232 of the substrate 230. Mold material 310 may surround and separate adjacent IC devices 202.

Similarly, the substrate 230 includes a plurality of contact pads 342 that are electrically connected to the circuitry 236 extending between the top and bottom surfaces 232, 352 of the substrate 230. The circuitry 236 generally terminates at a contact pad 338 exposed on the bottom surface 352 of the substrate 230. The substrate 230 may include a core 324 that has interconnect layers 322, 336 formed on either side. Each interconnect layer 322, 336 includes patterned metal layers that form portions of the circuitry 236. The core 324 typically includes a conductive via that couples the portions of the circuitry 236 formed in each interconnect layer 322, 336.

The interconnect layer 322 includes a plurality of contact pads 342 that are separated by an internal dielectric layer 346. Each bond pad 234 is formed on and electrically connected to a respective one of the contact pads 342. In one example, the bond pad 234 is formed from plated copper that is disposed on a copper seed layer 344. Each bond pad 234 is separated from each other by an external dielectric layer 348. The dielectric layer 348 is selected from a material suitable for hybrid bonding to the dielectric material of the external dielectric layer 308. In one example, the dielectric layers 308, 348 are made of the same type of material, for example, polybenzoxazole (PBO), polyimide (PI), benzocyclobutene (BCB), a combination thereof or the like.

As the dielectric layer 308 and the bond pads 214 of the IC device 202 are pressed against the exposed the dielectric layer 348 and the bond pads 234 of the substrate 230, the dielectric layers 308, 348 bond together as illustrated in FIG. 3. With the optional application of heat, the bond pads 214, 234 of the IC device 202 and substrate 230 bond together to mechanically connect the IC devices 202 to the substrate 230, and to electrically connect the functional circuitry 236 of the IC devices 202 to the circuitry 236 of the substrate 230.

At operation 110, the carrier 204 (and optional carrier 330) are removed to form a chip package 400, as illustrated in FIG. 4. In the example depicted in FIG. 4, the substrate 230 of the chip package 400 is shown as an interposer that is mechanically and electrically connected to a package substrate 402 by solder connections 404. The package substrate 402 is configured to be mechanically and electrically connected to a printed circuit board 406 (shown in phantom) by solder balls 408 to form an electronic device 450. In other embodiments, an interposer is not present and the substrate 230 of the chip package 400 is in the form of a package substrate.

In some embodiment and as illustrated in FIG. 3, exposed contact surfaces 360, 362 of the bond pads 214, 234 have an orientation that parallel to the plane of the top surface of the substrate 230 and the bottom surface 212 of the IC device. However, contact surfaces 360, 362 may be configured to have a greater contact surface area than a sectional area of the bond pads 214, 234 taken in the plane of the top surface 232 of the substrate 230 and the bottom surface 212 of the IC device. The increased contact surface area improved the performance of the diffusion bond between the bond pads 214, 234. For example, the increased contact surface area improves the mechanical strength and reliability of diffusion bond between the bond pads 214, 234. The increased contact surface area also improves the electrical performance of the interface between the bond pads 214, 234.

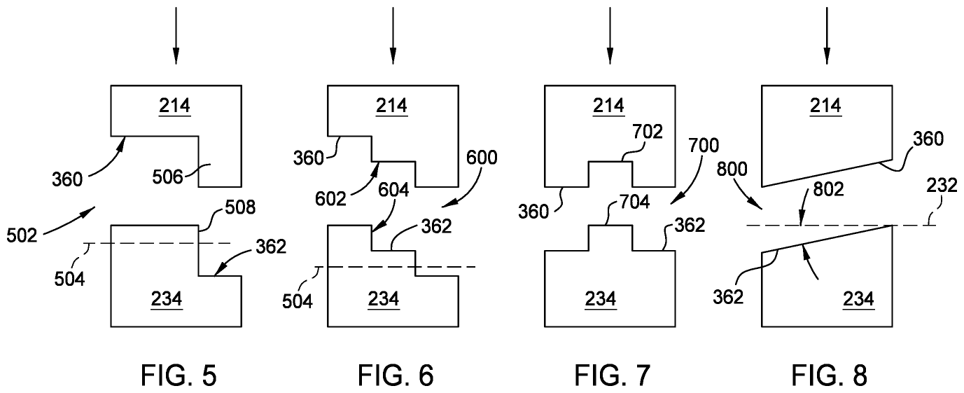

FIGS. 5-8 are schematic partial sectional exploded views of various bonding interfaces between the bond pads 214, 234 of the substrate 230 and the IC device 202 illustrating an increased contact surface area over a contact area that would be planar and parallel to the plane of the top surface 232 of the substrate 230 and the bottom surface 212 of the IC device. Although the IC device 202 and the substrate 230 are not shown in FIGS. 5-8, the bond pads 214 are part of the IC device 202 while the bond pads 234 are part of the substrate 230, such as illustrated in FIG. 2.

Referring first to FIG. 5, a bonding interface 502 is illustrated between contact surfaces 360, 362 of the bond pads 214, 234. The contact surfaces 360, 362 are pressed together at an elevated temperature to bond the bond pads 214, 234 together. As the bonding interface 502 of the contact surfaces 360, 362 is not planar, the contact surfaces 360, 362 have greater surface area as compared to a sectional area of the bond pads 214, 234 taken through a section line 504 that is parallel to a plane of the top surface 232 of the substrate 230 and the bottom surface 212 of the IC device 202. In the example depicted in FIG. 5, one of the contact surfaces 360, 362 has a projection 506 while the other of the contact surfaces 360, 362 has a recess 508 so that the contact surfaces mate across the bonding interface 502, thus providing a long surface for the bond pads 214, 234 to diffusion bond together, forming a robust electrical and mechanical connection between the IC device 202 and the substrate 230.

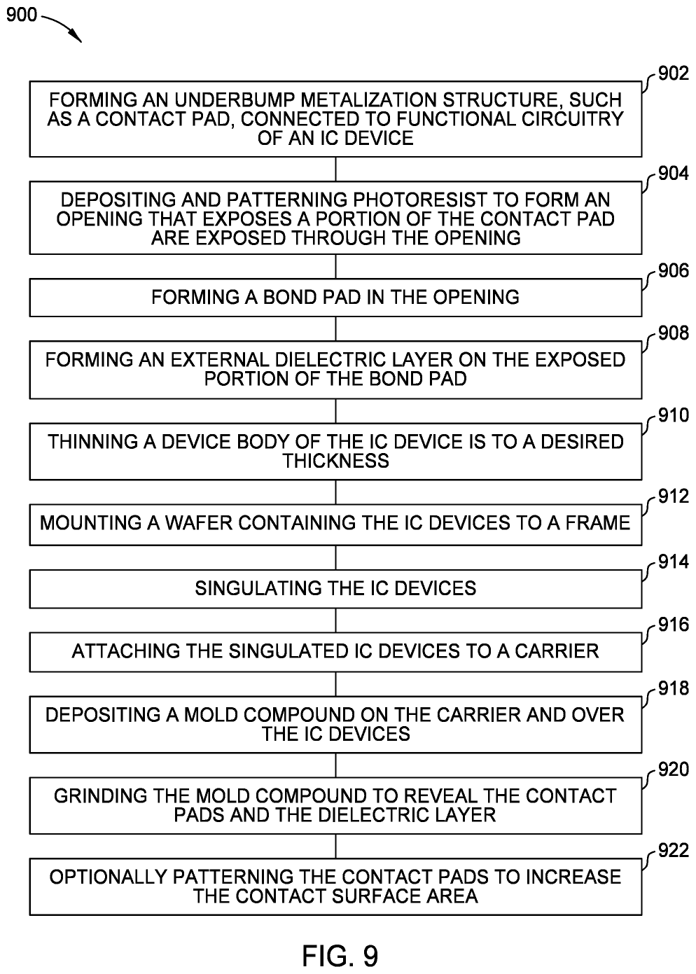

FIG. 6 depicts another example of a bonding interface 600 between the bond pads 214, 234 of the substrate 230 and the IC device 202. The bonding interface 602 the contact surfaces 360, 362 are also not planar. The contact surface 360 includes one or more steps 602, while the contact surface 362 includes one or more steps 604. The steps 602 are complimentary to the steps 604, such that the steps 602, 604 comprising the contact surfaces 360, 362 mate across the bonding interface 600, thus providing a long surface for the bond pads 214, 234 to diffusion bond together as compared to a planar bonding interface as shown in FIG. 2 that are parallel to the plane of the substrate 230.

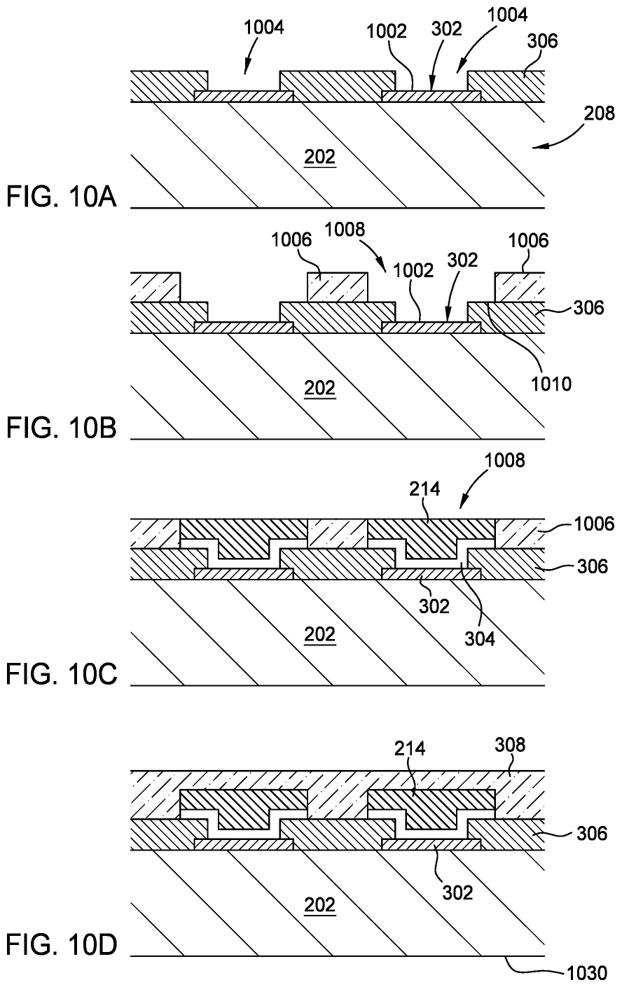

FIG. 7 depicts another example of a bonding interface 700 between the bond pads 214, 234 of the substrate 230 and the IC device 202. The bonding interface 700 of the contact surfaces 360, 362 is not planar such that the contact surfaces 360, 362 have greater surface area as compared to a sectional area of the bond pads 214, 234 taken through a section line 504 that is parallel to a plane of the top surface 232 of the substrate 230 and the bottom surface 212 of the IC device 202. In the example depicted in FIG. 7, one of the contact surfaces 360, 362 has a recess 702, while the other of the contact surfaces 360, 362 has a complimentary projection 704. The projection 704 is configured to closely fit into the recess 702 so that the contact surfaces 360, 362 mate across the bonding interface 700, thus providing a long surface for the bond pads 214, 234 to diffusion bond together, forming a robust electrical and mechanical connection between the IC device 202 and the substrate 230.

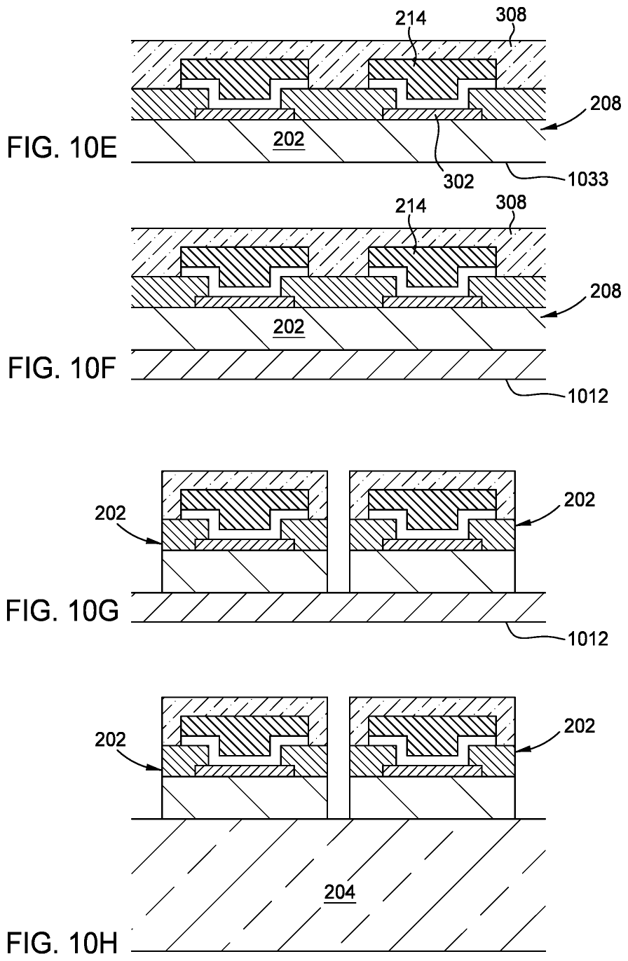

FIG. 8 depicts another example of a bonding interface 800 between the bond pads 214, 234 of the substrate 230 and the IC device 202. In the example depicted in FIG. 8, the contact surfaces 360, 362 are parallel to each other, and disposed at an acute angle 802 relative to the top surface 232 of the substrate 230. From a different point of reference, the angle 802 is less than 90 degrees relative to the plane of the substrate 230. Being that the contact surfaces 360, 362 are parallel to each other and disposed at an angle 802 relative to the plane of the substrate 230, the bonding interface 800 provides a long surface for the bond pads 214, 234 to diffusion bond together as compared to the contact surfaces 360, 362 illustrated in FIG. 2 that are parallel to the plane of the substrate 230, thus forming a robust electrical and mechanical connection between the IC device 202 and the substrate 230.

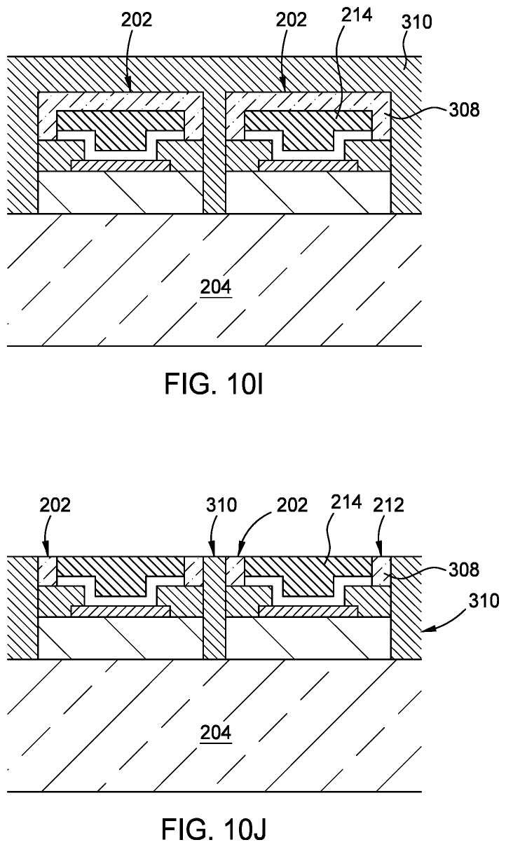

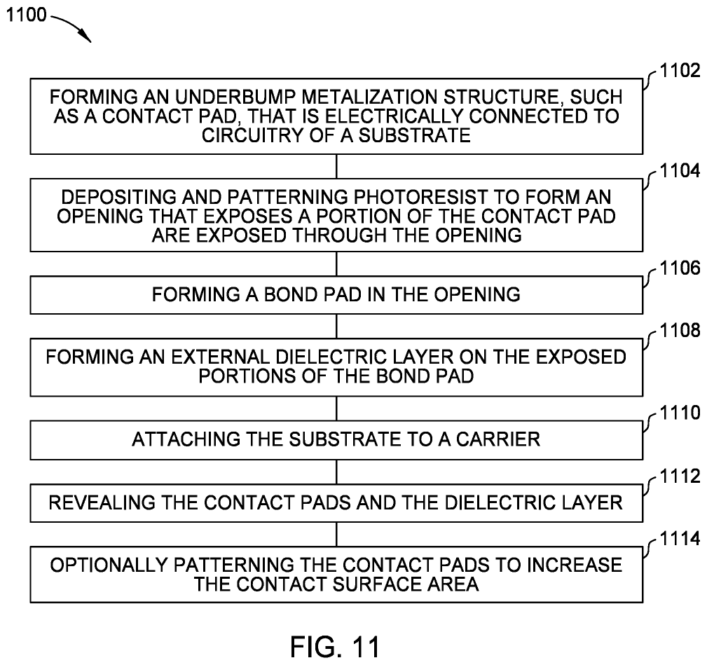

FIG. 9 is a flow diagram of a first portion of a method 900 for preparing IC devices 202 for inclusion in a chip package, such as the chip package 400 illustrated in FIG. 4. The method 900 may also be used for preparing IC devices 202 for chip packages having configurations other than what is illustrated in FIG. 4. FIGS. 10A-10J are schematic sectional views of an IC device 202 shown processing through various stages of preparation in accordance to the method 900 described in FIG. 9. Operations 902-912 are generally performed while IC devices 202 are still part of a larger semiconductor wafer.

The method 900 begins at operation 902 by forming an underbump metalization structure, such as the contact pad 302, that is electrically connected to the functional circuitry 210 of the IC device 202. The internal dielectric layer 306 is formed and patterned over the contact pads 302, leaving a portion 1002 of the contact pad 302 exposed through an opening 1004 formed in the dielectric layer 306.

At operation 904, photoresist 1006 is deposited and patterned over the dielectric layer 306 forming an opening 1008. A portion 1010 of the top surface of the dielectric layer 306 and the exposed portion 1002 of the contact pad 302 are exposed through the opening 1008 in the dielectric layer 306.

At operation 906, a bond pad 214 is formed in the opening 1008. The bond pad 214 makes electrical contact with the exposed portion 1002 of the contact pad 302. Optionally, a copper seed layer 304 may be disposed over the exposed portion 1002 of the contact pad 302 to facilitate plating of the bond pad 214 on the contact pad 302. The photoresist 1006 is removed after formation of the bond pad 214.

At operation 908, an external dielectric layer 308 is formed on the exposed portions of the top surface of the dielectric layer 306 and the bond pad 214. The dielectric layer 308 is selected from a material suitable for hybrid bonding to another dielectric material. In one example, the dielectric layer 308 is polybenzoxazole (PBO), polyimide (PI), benzocyclobutene (BCB), a combination thereof or the like.

At operation 910, the die bottom surface 1030 of the device body 208 is ground to thin the IC device 202 to a desired thickness.

At operation 912, the wafer containing the IC devices 202 are mounted to a frame 1012. The wafer is mounted to the frame 1012 using die attach tape or other suitable temporary adhesive to secure the ground die bottom surface 1030 of the device body 208 to the frame 1012. At operation 914, the IC devices 202 are singulated, for example by dicing the wafer with a wire saw, and removed from the frame 1012.

At operation 916, IC devices 202 are temporarily attached to a carrier 204. The IC devices 202 are mounted to the carrier 204 using a temporary adhesive, such as a die attach film or tape in a geometrical arrangement identical to the geometrical arrangement in which the IC devices 202 will have in the finished chip package.

In one example, a single IC device 202 may be attached on the carrier 204. In another example, one or more IC devices 202 in the form of IC dies 202_{D} along with one or more IC devices 202 in the form of chiplets 202_{C} may be attached on the carrier 204. In yet another example, one or more IC devices 202 in the form of IC logic dies 202_{D} along with one or more IC devices 202 in the form of a stack of IC memory dies 202_{D} or chiplets 202_{C} may be attached on the carrier 204.

At operation 918, a mold material 208 is deposited on the carrier 204 and over the IC devices 202. The mold material 208 separates the IC devices 202 and covers the dielectric layer 308. At operation 920, the mold material 208 is ground to reveal the bond pads 214 and the dielectric layer 308.

At optionally operation 922, the bond pads 214 are patterned to increase the contact surface area, such as described above with reference to FIGS. 5-8. The contact surface 360 of the bond pads 214 may be patterned or otherwise worked to have a non-planar geometry or an orientation that is not parallel to the plane of the bottom surface 212 of the IC device 202. Thus, the contact surfaces 360 will have a greater contact surface area than a sectional area of the bond pads 214 taken in the plane of the bottom surface 212 of the IC device 202. The increased contact surface area improved the performance of the diffusion bond between the bond pads 214, 234.

In one example, the bond pads 214 may be patterned by disposing a patterned resist layer that has opening through which a portion of the bond pads 214 are exposed. The exposed portion of the bond pads 214 are then etched to form a step, recess or other structure that may be mated with a mirror image structure formed in the bond pad 234 of the substrate 230.

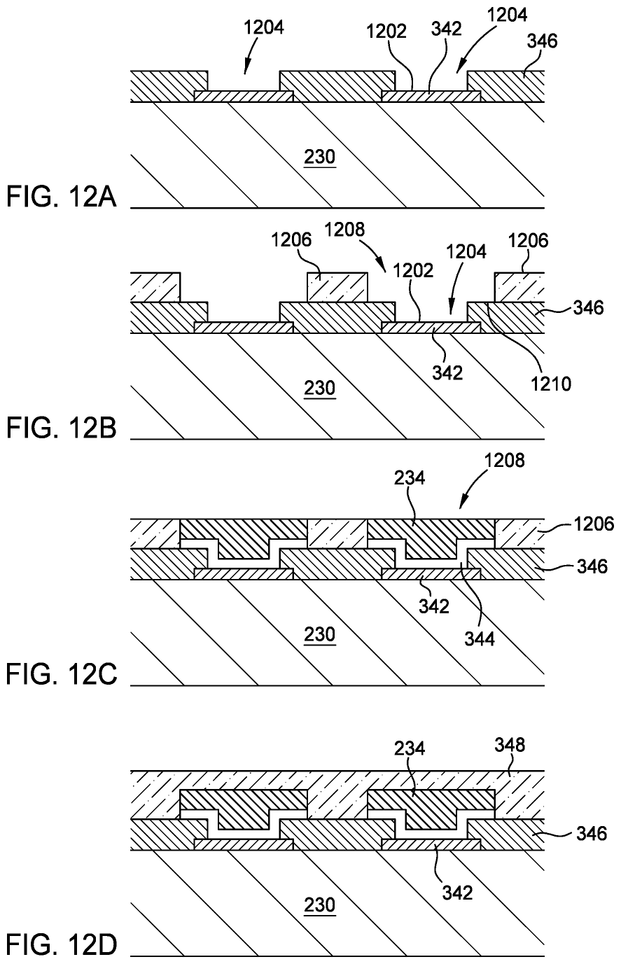

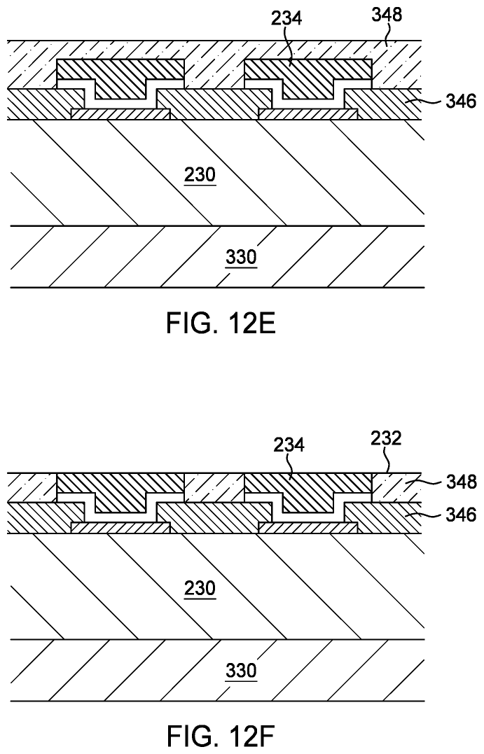

FIG. 11 is a flow diagram of a method 1100 for preparing a substrate 230 for inclusion in a chip package, such as the chip package 400 illustrated in FIG. 4. The method 1100 may also be used for preparing substrates 230 for chip packages having configurations other than what is illustrated in FIG. 4. FIGS. 12A-12F are schematic sectional views of the substrate 230 shown processing through various stages of preparation in accordance to the method described in FIG. 11.

The method 1100 begins at operation 1102 by forming an underbump metalization structure, such as the contact pad 342 that is electrically connected to the circuitry 236 of the substrate 230. The internal dielectric layer 346 is formed and patterned over the contact pads 342, leaving a portion 1202 of the contact pad 342 exposed through an opening 1204 formed in the dielectric layer 346.

At operation 1104, photoresist 1206 is deposited and patterned over the dielectric layer 346 forming an opening 1208. A portion 1210 of the top surface of the dielectric layer 346 and the exposed portion 1202 of the contact pad 342 are exposed through the opening 1208.

At operation 1106, a bond pad 234 is formed in the opening 1208. The bond pad 234 makes electrical contact with the exposed portion 1202 of the contact pad 342. Optionally, a copper seed layer 344 may be disposed over the exposed portion 1202 of the contact pad 342 to facilitate plating of the bond pad 234 on the contact pad 342. The photoresist 1206 is removed after formation of the bond pad 234.

At operation 1108, an external dielectric layer 348 is formed on the exposed portions of the top surface of the dielectric layer 346 and the bond pad 234. The dielectric layer 348 is selected from a material suitable for hybrid bonding to another dielectric material. In one example, the dielectric layer 348 is the same materials used for the dielectric layer 308, such as polybenzoxazole (PBO), polyimide (PI), benzocyclobutene (BCB), a combination thereof or the like.

At operation 1110, substrate 230 is temporarily attached to a carrier 330. The substrate 230 is mounted to the carrier 330 using a temporary adhesive, such as a die attach film or tape. At operation 1112, a portion of the mold material 310 is removed to reveal the bond pads 234.

At optionally operation 1114, the bond pads 234 are patterned to increase the contact surface area, such as described above with reference to FIGS. 5-8. The contact surface 362 of the bond pads 234 may be patterned or otherwise worked to have a non-planar geometry or an orientation that is not parallel to the plane of the top surface 232 of the substrate 230. The geometry of the contact surface 362 is complimentary to, and the mirror image of the contact surfaces 360. In one example, the bond pads 234 may be patterned by disposing a patterned resist layer that has opening through which a portion of the bond pads 234 are exposed. The exposed portion of the bond pads 234 are then etched to form a step, recess or other structure that may be mated with a mirror image structure formed in the bond pad 214 of the IC device 202.

After the methods 900 and 1100 are complete, the substrate 230 and IC devices 202 disposed on the carrier 204 are hybrid bonded together, for example as described above with reference to the method of FIG. 1, or other suitable hybrid bonding technique. The hybrid bonding bonds the dielectric layers 308, 348 together, while diffusion bonding the contact surfaces 360, 362 of the bond pads 214, 234. After the hybrid bonding is complete, the carriers 204, 330 are removed, leaving the IC devices mounted to the substrate 230 to form a chip package, such as shown in the example of FIG. 4.

Thus, a chip package and method for fabricating the same have been described that includes hybrid bonding configured to improve the formation of sub-micron fine pitches between interconnects, improves warpage resistance, and eliminates flux residue. In some examples, the hybrid bond across the interconnect interface is not completely parallel to the plane of the substrate, which desirably increases the surface area available for hybrid bonding, resulting in increased bond strength, improved electrical performance, and more relaxed tolerances. As an end result, the chip package with hybrid bonded interface provide improved reliability and performance over conventional solder interface designs.

While the foregoing is directed to embodiments of the present invention, other and further embodiments of the invention may be devised without departing from the basic scope thereof, and the scope thereof is determined by the claims that follow.

What is claimed is:

1. A chip package comprising:
a substrate having a die side and a ball side, the die side having a plurality of exposed metal bond pads; and
a plurality of integrated circuit (IC) devices each having a device body, the device body having functional circuitry formed therein and terminating a plurality of exposed metal bond pads, the plurality of exposed metal bond pads hybrid bonded to the plurality of exposed metal bond pads.

2. The chip package of claim 1, wherein the plurality of IC devices further comprises:
a first IC die hybrid bonded to the plurality of exposed metal bond pads; and
at least one or more chiplets hybrid bonded to the plurality of exposed metal bond pads.

3. The chip package of claim 2, wherein the plurality of IC devices further comprises:
a second IC die hybrid bonded to the plurality of exposed metal bond pads, wherein the second IC die is part of a memory stack.

4. The chip package of claim 1, wherein a first bond pad of the plurality of exposed metal bond pads has a surface area in contact with a first contact pad of the plurality of exposed metal bond pads that is greater than a sectional area of the first bond pad taken in a direction parallel to a plane of the substrate.

5. The chip package of claim 4, wherein the substrate is an interposer, and wherein the interposer is coupled to a package substrate via a plurality of solder interconnects.

6. The chip package of claim 4, wherein the surface area of the first bond pad in contact with the first contact pad is planar and non-parallel to the plane of the substrate.

7. The chip package of claim 4, wherein the surface area of the first bond pad in contact with the first contact pad has a first region parallel to the plane of the substrate and a second region non-parallel to the plane of the substrate.

8. The chip package of claim 7, wherein the second region is perpendicular to the plane of the substrate.

9. The chip package of claim 4, wherein the surface area of the first bond pad in contact with the first contact pad comprises one or more steps.

10. The chip package of claim 4, wherein a first bond pad of the plurality of exposed metal bond pads is in contact with a first contact pad of the plurality of exposed metal bond pads, one of the first contact or bond pad having a projection that is received in a pocket of the other of the first contact or bond pad.

11. The chip package of claim 4 further comprising:
a polymer layer filling an interstitial space between the plurality of exposed metal bond pads and the plurality of exposed metal bond pads.

12. A method for fabricating a chip package, the method comprising:
temporarily securing a plurality of integrated circuit (IC) devices to a carrier;
revealing a plurality of metal bond pads of each IC device disposed on the carrier;
mounting the IC devices secured to the carrier on a plurality of exposed metal bond pads of a substrate;
hybrid bonding the exposed metal bond pads of the substrate to the exposed metal bond pads of the IC devices disposed on the carrier to mechanically couple the IC devices to the substrate and electrically couple functional circuitry of the IC devices to circuitry formed through the substrate; and
removing the carrier to form the chip package.

13. The method of claim 12 further comprising:
forming contact surfaces of the plurality of metal bond pads that each have a contact surface having a surface area that is greater than a sectional area taken in a direction parallel to a plane of the substrate; and
forming contact surfaces of the plurality of metal bond pads that are complimentary to the contact surfaces of the plurality of metal bond pads.

14. The method of claim 12, wherein forming contact surfaces of the plurality of metal bond pads further comprises removing material from the contact surfaces of the plurality of metal bond pads.

15. The method of claim 14, wherein removing material from the contact surfaces of the plurality of metal bond pads further comprises:
patterning and etching the contact surfaces.

16. The method of claim 14, wherein removing material from the contact surfaces of the plurality of metal bond pads further comprises:
making the contact surfaces planar and non-parallel to the plane of the substrate.

17. The method of claim 14, wherein removing material from a first contact surface of a first metal bond pad of the plurality of metal bond pads comprises:
making a first region of the first contact surface parallel to the plane of the substrate; and
making a second region of the first contact surface non-parallel to the plane of the substrate.

18. The method of claim 17, wherein making the second region non-parallel to the plane of the substrate further comprises:
making the second region is perpendicular to the plane of the substrate.

19. The method of claim 14, wherein removing material from a first contact surface of a first metal bond pad of the plurality of metal bond pads comprises:
making one or more steps in the first contact surface.

20. The method of claim 12 further comprising:
inserting a projection extending from one pad of the plurality of metal contact or bond pads into a pocket formed in a complimentary pad of the other of the first contact or bond pad.
